(19) United States
(12) Patent Application Publication
(10) Pub. No.: US 2026/0246503 A1
(43) Pub. Date: Aug. 20, 2026

(54) CROSS-SEGMENT POWER MANAGEMENT SYSTEM IN A WIRELESS COMMUNICATION DEVICE

(71) Applicant: Qorvo US, Inc., Greensboro, NC (US)

(72) Inventor: Nadim Khlat, Ceret (FR)

(21) Appl. No.: 19/162,548

(22) PCT Filed: Jan. 9, 2024
(86) PCT No.: PCT/US2024/010798

§ 371 Date: Sep. 5, 2025

Related U.S. Application Data
(60) Provisional application No. 63/489,440, filed on Mar. 10, 2023.
(60) Provisional application No. 63/467,366, filed on May 18, 2023.

(51) Int. Cl. H04B 7/0426; H03F 3/24; H04B 7/0404

(52) U.S. Cl. CPC H04B 7/0426; H03F 3/245; H04B 7/0404; H03F 2200/451

(57) ABSTRACT

A cross-segment power management system is provided. In an embodiment, the cross-segment power management system can be provided in a wireless communication device to support multiple power amplifiers organized into multiple amplifier segments, such as a pair of amplifier segments provided on a top and a bottom of the wireless communication device. Moreover, the cross-segment power management system includes multiple voltage segments each capable of providing a modulated voltage(s) to any of the amplifier segments. Through the cross-segment power management system, the wireless communication device can be flexibly configured to perform multiple concurrent transmissions via most suitable antennas. As a result, it is possible to mitigate unintended interference (e.g., hand blocking) for better user experience.

### RELATED APPLICATIONS

This application claims the benefit of U.S. provisional patent application ser. no. 63/489,440, filed on Mar. 10, 2023, and U.S. provisional patent application ser. no. 63/467,366, filed on May 18, 2023, the disclosures of which are hereby incorporated herein by reference in their entireties.

### FIELD OF THE DISCLOSURE

The technology of the disclosure relates generally to a power management system in a wireless communication device.

### BACKGROUND

Mobile communication devices have become increasingly common in current society for providing wireless communication services. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

A state-of-the-art mobile communication device must be able to communicate a radio frequency (RF) signal(s) in a variety of wireless communication systems, such as long-term evolution (LTE) and new radio (NR), based on a variety of transmit/receive configurations, such as uplink/downlink multiple-input, multiple-output (UL/DL-MIMO), enhanced dual-connectivity (EN-DC), and diversity receive (DRX). As an example, many multi-transmission proposals have been made for third-generation partnership project (3GPP) release 18 to support concurrent UL-MIMO and EN-DC transmissions on multiple RF bands. In this regard, a wireless communication device is required to concurrently transmit at least three RF signals (2xMIMO+1xEN-DC).

### SUMMARY

Embodiments of the disclosure relate to a cross-segment power management system. In an embodiment, the cross-segment power management system can be provided in a wireless communication device to support multiple power amplifiers organized into multiple amplifier segments, such as a pair of amplifier segments provided on a top and a bottom of the wireless communication device. Moreover, the cross-segment power management system includes multiple voltage segments each capable of providing a modulated voltage(s) to any of the amplifier segments. Through the cross-segment power management system, the wireless communication device can be flexibly configured to perform multiple concurrent transmissions via most suitable antennas. As a result, it is possible to mitigate unintended interference (e.g., hand blocking) for better user experience.

In one aspect, a cross-segment power management system is provided. The cross-segment power management system includes a first amplifier segment that includes at least two first power amplifiers. The cross-segment power management system also includes a second amplifier segment that includes at least three second power amplifiers. The cross-segment power management system also includes a first voltage segment. The first voltage segment is configured to generate at least two first modulated voltages. The cross-segment power management system also includes a second voltage segment. The second voltage segment is configured to generate at least three second modulated voltages. The cross-segment power management system also includes a control circuit. The control circuit is configured to cause at least two of the at least two first modulated voltages and the at least three second modulated voltages to be provided to at least two of the at least two first power amplifiers and the at least three second power amplifiers, respectively.

In another aspect, a wireless communication device is provided. The wireless communication device includes a cross-segment power management system. The cross-segment power management system includes a first amplifier segment that includes at least two first power amplifiers. The cross-segment power management system also includes a second amplifier segment that includes at least three second power amplifiers. The cross-segment power management system also includes a first voltage segment. The first voltage segment is configured to generate at least two first modulated voltages. The cross-segment power management system also includes a second voltage segment. The second voltage segment is configured to generate at least three second modulated voltages. The cross-segment power management system also includes a control circuit. The control circuit is configured to cause at least two of the at least two first modulated voltages and the at least three second modulated voltages to be provided to at least two of the at least two first power amplifiers and the at least three second power amplifiers, respectively.

In another aspect, a method for providing cross-segment power management in a wireless communication device is provided. The method includes generating at least two first modulated voltages in a first voltage segment. The method also includes generating at least three second modulated voltages in a second voltage segment. The method also includes causing at least two of the at least two first modulated voltages and the at least three second modulated voltages to be provided to at least two of at least two first power amplifiers and at least three second power amplifiers, respectively.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a schematic diagram of an exemplary wireless communication device incorporating a cross-segment power management system of the present disclosure;

FIG. 2 is a schematic diagram of the cross-segment power management system in FIG. 1;

FIGS. 3A-3C are schematic diagrams providing exemplary illustrations of some operating scenarios of the cross-segment power management system of FIG. 2;

FIG. 4A is a schematic diagram of an exemplary power management integrated circuit (PMIC) in the cross-segment power management system of FIG. 2 for generating an envelope tracking (ET) voltage;

FIG. 4B is a schematic diagram of an exemplary lightweight PMIC (PMICLite) in the cross-segment power management system of FIG. 2 for generating the ET voltage;

FIG. 5A is a schematic diagram of an exemplary PMIC in the cross-segment power management system of FIG. 2 for generating an average power tracking (APT) voltage;

FIG. 5B is a schematic diagram of an exemplary PMICLite in the cross-segment power management system of FIG. 2 for generating the APT voltage;

FIG. 6 is a schematic diagram of an exemplary user element wherein the cross-segment power management system of FIG. 2 can be provided; and

FIG. 7 is a flowchart of an exemplary process whereby the wireless communication device of FIG. 1 can be configured to support cross-segment power management.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to a cross-segment power management system. In an embodiment, the cross-segment power management system can be provided in a wireless communication device to support multiple power amplifiers organized into multiple amplifier segments, such as a pair of amplifier segments provided on a top and a bottom of the wireless communication device. Moreover, the cross-segment power management system includes multiple voltage segments each capable of providing a modulated voltage(s) to any of the amplifier segments. Through the cross-segment power management system, the wireless communication device can be flexibly configured to perform multiple concurrent transmissions via most suitable antennas. As a result, it is possible to mitigate unintended interference (e.g., hand blocking) for better user experience.

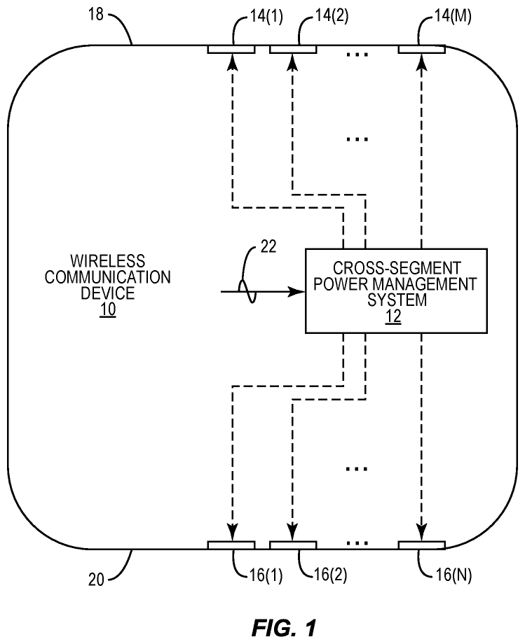

FIG. 1 is a schematic diagram of an exemplary wireless communication device 10 incorporating a cross-segment power management system 12 of the present disclosure. The wireless communication device 10 (e.g., a smartphone) includes multiple first antennas 14(1)-14(M) (M≥2) and multiple second antennas 16(1)-16(N) (N≥3). The first antennas 14(1)-14(M) and the second antennas 16(1)-16(N) are typically provided on opposite edges of the wireless communication device 10 (e.g., a top edge 18 and a bottom edge 20) to help mitigate unintended interference caused by, for example, hand blocking.

In addition, the first antennas 14(1)-14(M) and/or the second antennas 16(1)-16(N) can also be used to enable multiple concurrent transmissions, including but not limited to concurrent uplink multiple-input multiple-output (UL-MIMO) and enhanced dual-connectivity (EN-DC) transmissions. As described in detail below, the cross-segment power management system 12 can be flexibly and dynamically configured to amplify one or more radio frequency (RF) signals 22 for concurrent transmissions via any suitable combination of the first antennas 14(1)-14(M) and the second antennas 16(1)-16(N). As a result, the wireless communication device 10 can transmit the RF signals 22 via the most suitable antennas to thereby improve RF performance and end user experience.

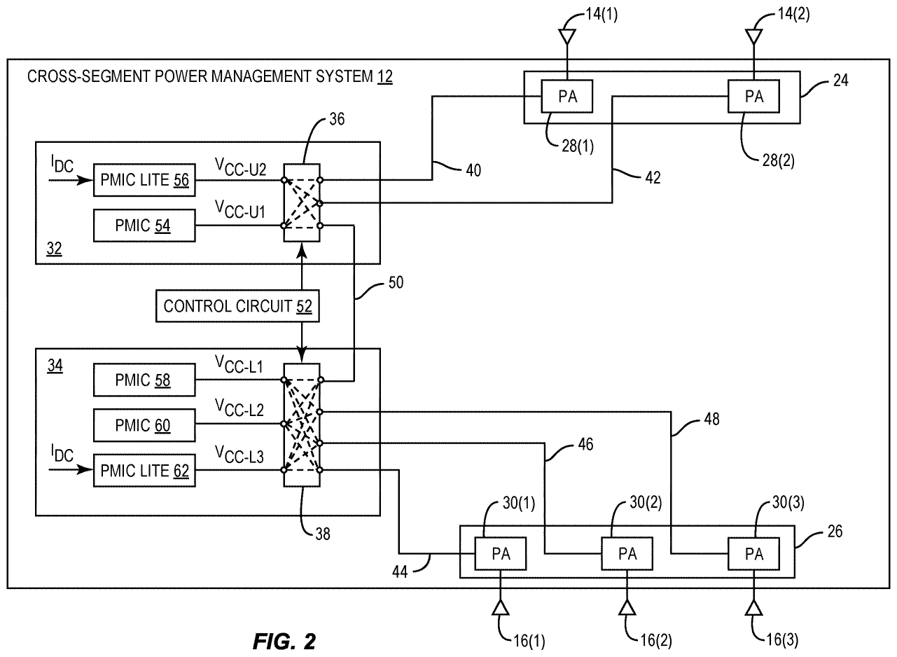

FIG. 2 is a schematic diagram illustrating the cross-segment power management system 12 configured according to an embodiment of the present disclosure. Common elements between FIGS. 1 and 2 are shown therein with common element numbers and will not be re-described herein.

In an embodiment, the cross-segment power management system 12 is configured to support at least two of the first antennas 14(1)-14(M) (denoted as “14(1), 14(2)” for the purpose of illustration) and at least three of the second antennas 16(1)-16(N) (denoted as “16(1), 16(2), 16(3)” for the purpose of illustration) in the wireless communication device 10 of FIG. 1. In a non-limiting example, the first antennas 14(1), 14(2) are provided on the top edge 18 of the wireless communication device 10 whereas the second antennas 16(1), 16(2), 16(3) are provided on the bottom edge 20 of the wireless communication device 10.

According to an embodiment of the present disclosure, the cross-segment power management system 12 includes a first amplifier segment 24 and a second amplifier segment 26. The first amplifier segment 24 includes at least two first power amplifiers 28(1), 28(2) that are coupled to the first antennas 14(1), 14(2), respectively. The second amplifier segment 26 includes at least three second power amplifiers 30(1), 30(2), 30(3) that are coupled to the second antennas 16(1), 16(2), 16(3), respectively.

In an embodiment, the first power amplifiers 28(1), 28(2) are provided closer to the top edge 18 of the wireless communication device 10 and, therefore, closer to the first antennas 14(1), 14(2). In contrast, the second power amplifiers 30(1), 30(2), 30(3) are provided closer to the bottom edge 20 of the wireless communication device 10 and, therefore closer to the second antennas 16(1), 16(2), 16(3). By providing the first power amplifiers 28(1)-28(2) closer to the first antennas 14(1)-14(2) and providing the second power amplifiers 30(1)-30(3) closer to the second antennas 16(1)-16(3), it is possible to reduce coupling distances to the respective antennas. As a result, it is possible to reduce signal distortions associated with the coupling distances.

The cross-segment power management system 12 also includes a first voltage segment 32 and a second voltage segment 34. The first voltage segment 32 is configured to generate at least two first modulated voltages V_{CC-U1} and V_{CC-U2} whereas the second voltage segment 34 is configured to generate at least three second modulated voltages V_{CC-L1}, V_{CC-L2}, and V_{CC-L3}.

The first voltage segment 32 also includes a first switch circuit 36, which is coupled to the first power amplifiers 28(1) and 28(2) via at least two first local voltage lines 40 and 42. Thus, by controlling the first switch circuit 36, it is possible to provide any of the first modulated voltages V_{CC-U1} and V_{CC-U2} to any of the first power amplifiers 28(1) and 28(2). In an embodiment, the first voltage segment 32 is provided closer to the first power amplifiers 28(1) and 28(2) than to any of the second power amplifiers 30(1)-30(3). As such, the first local voltage lines 40 and 42 can be shortened to reduce distortions in the first modulated voltages V_{CC-U1} and V_{CC-U2}.

The second voltage segment 34 also includes a second switch circuit 38, which is coupled to the second power amplifiers 30(1)-30(3) via at least three second local voltage lines 44, 46, and 48. Thus, by controlling the second switch circuit 38, it is possible to provide any of the second modulated voltages V_{CC-L1}, V_{CC-L2}, and V_{CC-L3} to any of the second power amplifiers 30(1)-30(3). In an embodiment, the second voltage segment 34 is provided closer to the second power amplifiers 30(1)-30(3) than to any of the first power amplifiers 28(1) and 28(2). As such, the second local voltage lines 44, 46, and 48 can be shortened to reduce distortions in the second modulated voltages V_{CC-L1}, V_{CC-L2}, and V_{CC-L3}.

According to an embodiment of the present disclosure, the cross-segment power management system 12 also includes a cross-segment line 50 that is shared by the first voltage segment 32 and the second voltage segment 34. In this regard, the first switch circuit 36 can be further controlled to provide any of the first modulated voltages V_{CC-U1} and V_{CC-U2} to any of the second power amplifiers 30(1)-30(3), and the second switch circuit 38 can be further controlled to provide any of the second modulated voltages V_{CC-L1}, V_{CC-L2}, and V_{CC-L3} to any of the first power amplifiers 28(1) and 28(2).

Herein, the cross-segment power management system 12 also includes a control circuit 52, which can be a field-programmable gate array (FPGA) or an application-specific integrated circuit (ASIC), as an example. The control circuit 52 can be configured to selectively and dynamically control the first switch circuit 36 and/or the second switch circuit 38 to provide at least two modulated voltages among the first modulated voltages V_{CC-U1}, V_{CC-U2} and the second modulated voltages V_{CC-L1}, V_{CC-L2}, V_{CC-L3} to the first power amplifiers 28(1) and 28(2) in the first amplifier segment 24, and provide at least three modulated voltages among the first modulated voltages V_{CC-U1}, V_{CC-U2} and the second modulated voltages V_{CC-L1}, V_{CC-L2}, V_{CC-L3} to the second power amplifiers 30(1)-30(3) in the second amplifier segment 26. In this regard, the control circuit 52 can selectively and dynamically control the first switch circuit 36 and/or the second switch circuit 38 to enable local and cross segment voltage coupling in the cross-segment power management system 12.

According to an embodiment of the present disclosure, the first voltage segment 32 includes a first power management integrated circuit (PMIC) 54 and a first lightweight PMIC (PMICLite) 56. The first PMIC 54 is configured to generate the first modulated voltage V_{CC-U1} and the first PMICLite 56 is configured to generate the first modulated voltage V_{CC-U2}. As further discussed later, the first PMICLite 56 includes fewer components than the first PMIC 54 and, therefore, has a smaller footprint relative to the first PMIC 54.

Similarly, the second voltage segment 34 includes a pair of second PMICs 58, 60 as well as a second PMICLite 62. The second PMICs 58, 60 are configured to generate the second modulated voltages V_{CC-L1}, V_{CC-L2}, respectively, and the second PMICLite 62 is configured to generate the second modulated voltage V_{CC-L3}. Like the first PMICLite 56, the second PMICLite 62 also has a smaller footprint relative to the second PMICs 58, 60.

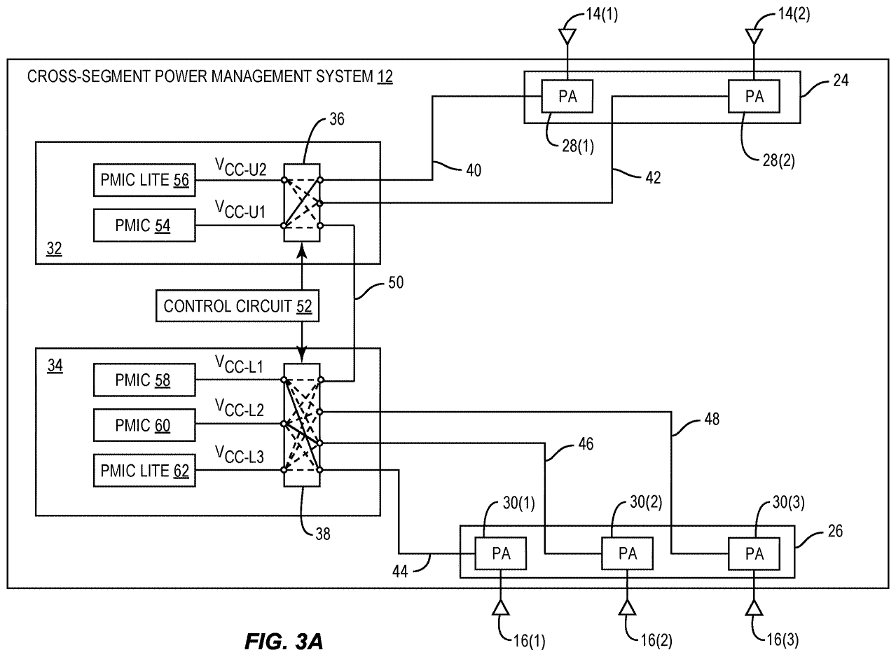

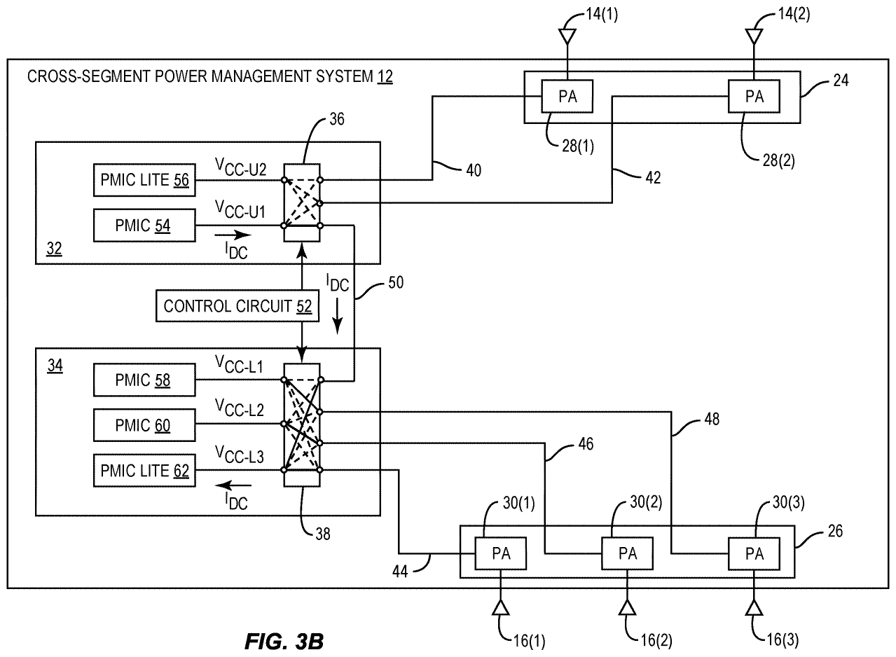

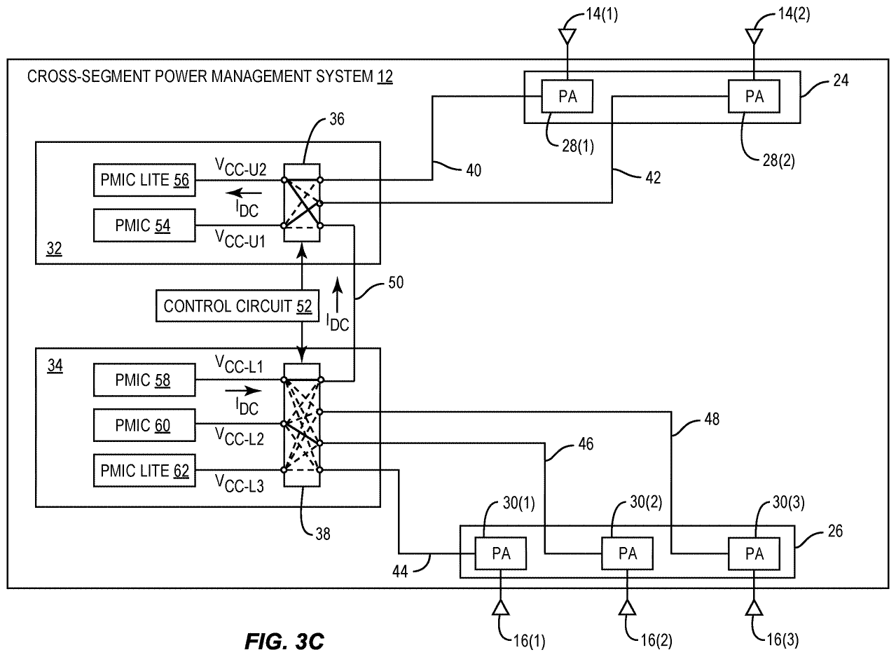

FIGS. 3A-3C are schematic diagrams providing exemplary illustrations of some operating scenarios of the cross-segment power management system 12 of FIG. 2. Common elements between FIGS. 2 and 3A-3C are shown therein with common element numbers and will not be re-described herein.

With reference to FIG. 3A, the cross-segment power management system 12 can support three simultaneous transmissions via a selected one of the first antennas 14(1), 14(2) and a selected two of the second antennas 16(1)-16(3). In this regard, the control circuit 52 may control the first switch circuit 36 to provide the first modulated voltage V_{CC-U1} to the selected one of the first power amplifiers 28(1)-28(2) (e.g., 28(1)) and control the second switch circuit 38 to couple the second modulated voltages V_{CC-L1} and V_{CC-L2} to the selected two of the second power amplifiers 30(1)-30(3) (e.g., 30(1), 30(2)). In a non-limiting example, the control circuit 52 can deactivate the first PMICLite 56 and the second PMICLite 62.

With reference to FIG. 3B, the cross-segment power management system 12 can support three simultaneous transmissions via the second antennas 16(1)-16(3). In this regard, the control circuit 52 may control the second switch circuit 38 to couple each of the second modulated voltages V_{CC-L1}, V_{CC-L2}, V_{-L3} to a respective one of the second power amplifiers 30(1)-30(3). The control circuit 52 further controls the first switch circuit 36 to couple the first PMIC 54 to the cross-segment line 50 such that the first PMIC 54 can provide a low-frequency current loc to the second PMICLite 62. In a non-limiting example, the control circuit 52 can deactivate the first PMICLite 56.

With reference to FIG. 3C, the cross-segment power management system 12 can support three simultaneous transmissions via the first antennas 14(1), 14(2) and a selected one of the second antennas 16(1)-16(3). In this regard, the control circuit 52 may control the first switch circuit 36 to provide the first modulated voltages V_{CC-U2}, V_{CC-U1} to the first power amplifiers 28(1) and 28(2), respectively, and control the second switch circuit 38 to couple the second modulated voltage V_{CC-L2} to one of the second power amplifiers 30(1)-30(3) (e.g., 30(2)). The control circuit 52 also controls the second switch circuit 38 to couple the second PMIC 58 to the cross-segment line 50 such that the second PMIC 58 can provide the low-frequency current loc to the first PMICLite 56. In a non-limiting example, the control circuit 52 can deactivate the first PMIC 54.

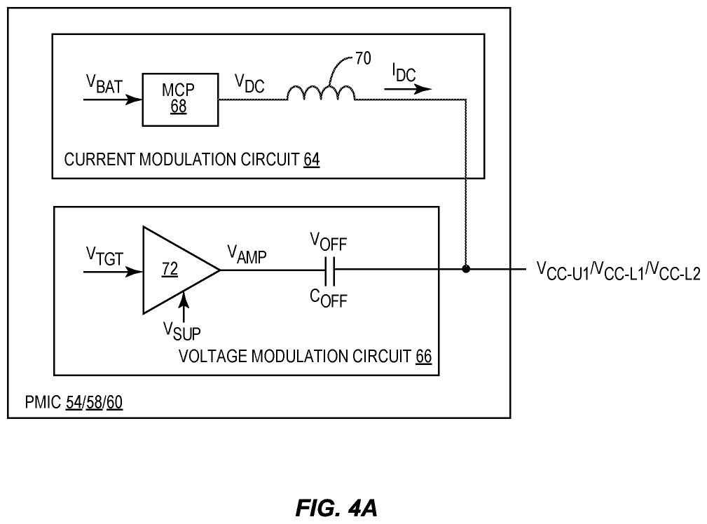

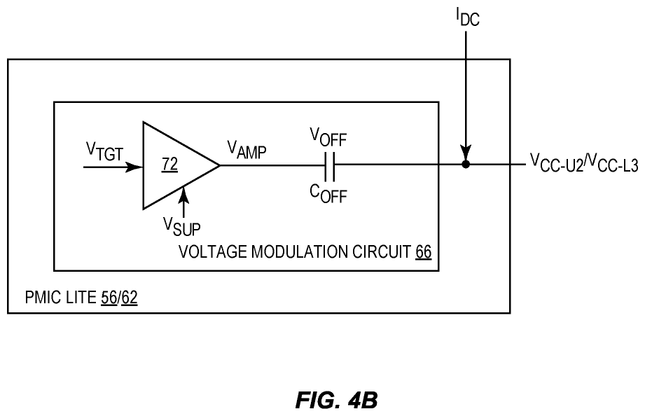

In one embodiment, the first modulated voltages V_{CC-U1}, V_{CC-U2} and the second modulated voltages V_{CC-L1}, V_{CC-L2}, V_{CC-L3} can be envelope tracking (ET) voltages. In this regard, FIG. 4A is a schematic diagram providing an exemplary illustration of the first PMIC 54 and the second PMICs 58, 60 in the cross-segment power management system 12 of FIG. 2. Common elements between FIGS. 2 and 4A are shown therein with common element numbers and will not be re-described herein.

Each of the first PMIC 54 and the second PMICs 58, 60 can be configured to include a current modulation circuit 64 and a voltage modulation circuit 66. The current modulation circuit 64 includes a multi-level charge pump (MCP) 68 and a power inductor 70 that are coupled in series. In an embodiment, the MCP 68 can be a buck-boost direct-current-direct-current (DC-DC) voltage converter configured to generate a low-frequency voltage V_{DC} as a function of a battery voltage V_{BAT}. For instance, the MCP 68 can operate in a buck mode to generate the low-frequency voltage V_{DC} at 0×V_{BAT} (0 volt) or 1×V_{BAT} or operate in a boost mode to generate the low-frequency voltage V_{DC} at 2×V_{BAT}. Moreover, the MCP 68 can be configured to toggle between the buck mode and the boost mode in accordance with a duty cycle to thereby change the low-frequency voltage V_{DC}. The power inductor 70, in turn, induces the low-frequency current I_{DC} based on the low-frequency voltage V_{DC}.

The voltage modulation circuit 66 includes a voltage amplifier 72 and an offset capacitor C_{OFF} that are coupled in series. The voltage amplifier 72 is configured to generate an initial modulated voltage V_{AMP} based on a modulated ET target voltage V_{TGT} and a supply voltage V_{SUP}. The offset capacitor C_{OFF} is configured to raise the initial modulated voltage V_{AMP} by an offset voltage V_{OFF} to thereby generate the first modulated voltage V_{CC-U1} and the second modulated voltages V_{CC-L1}, V_{CC-L2} (V_{CC-U1}, V_{CC-L1}, V_{CC-L2}=V_{AMP}+V_{OFF}). Herein, the offset capacitor C_{OFF} can be charged to the offset voltage V_{OFF} by the low-frequency current I_{DC}.

FIG. 4B is a schematic diagram providing an exemplary illustration of the first PMICLite 56 and the second PMICLite 62 in the cross-segment power management system 12 of FIG. 2. Common elements between FIGS. 2, 4A, and 4B are shown therein with common element numbers and will not be re-described herein.

Herein, each of the first PMICLite 56 and the second PMICLite 62 includes the voltage modulation circuit 66 but not the current modulation circuit 64. As such, the first PMICLite 56 and the second PMICLite 62 can be smaller than any of the first PMIC 54 and the second PMICs 58, 60. Instead of generating the low-frequency current loc, each of the first PMICLite 56 and the second PMICLite 62 is configured to receive the low-frequency current loc from a neighboring PMIC. As an example, the first PMICLite 56 can receive the low-frequency current loc from the first PMIC 54, whereas the second PMICLite 62 can receive the low-frequency current loc from any of the second PMICs 58, 60. In another example, the first PMICLite 56 can receive the low-frequency current IDC from any of the second PMICs 58, 60 and the second PMICLite 62 can receive the low-frequency current loc from the first PMIC 54.

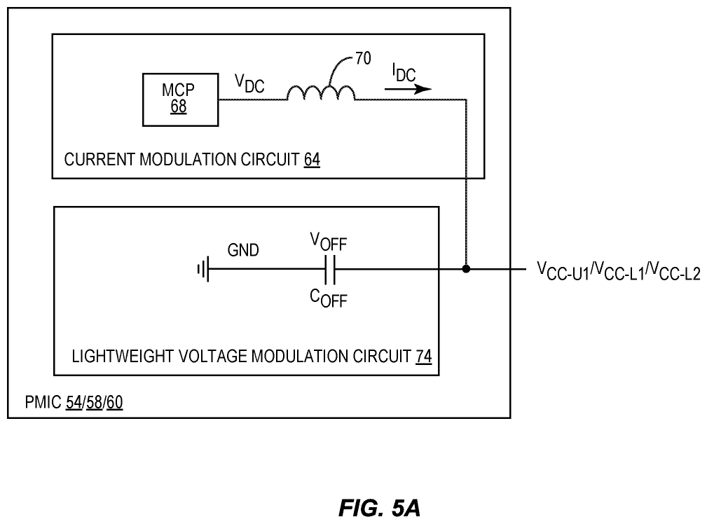

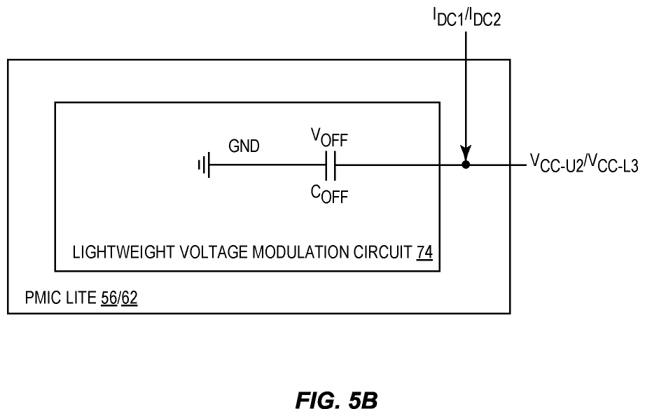

In another embodiment, the first modulated voltages V_{CC-U1}, V_{CC-U2} and the second modulated voltages V_{CC-L1}, V_{CC-L2}, V_{CC-L3} can be average power tracking (APT) voltages. In this regard, FIG. 5A is a schematic diagram providing an exemplary illustration of the first PMIC 54 and the second PMICs 58, 60 in the cross-segment power management system 12 of FIG. 2. Common elements between FIGS. 4A and 5A are shown therein with common element numbers and will not be re-described herein.

Herein, each of the first PMIC 54 and the second PMICs 58, 60 can be configured to replace the voltage modulation circuit 66 in FIG. 3A with a lightweight voltage modulation circuit 74. As shown, the lightweight voltage modulation circuit 74 includes only the offset capacitor COFF.

FIG. 5B is a schematic diagram providing an exemplary illustration of the first PMICLite 56 and the second PMICLite 62 in the cross-segment power management system 12 of FIG. 2. Common elements between FIGS. 5A and 5B are shown therein with common element numbers and will not be re-described herein.

As shown herein, each of the first PMICLite 56 and the second PMICLite 62 includes the lightweight voltage modulation circuit 74 but not the current modulation circuit 64 in FIG. 5A.

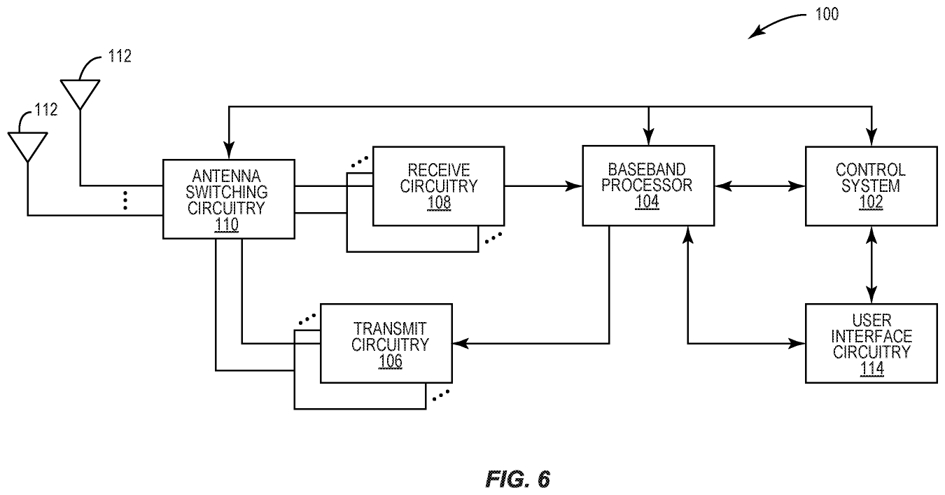

The cross-segment power management system 12 of FIG. 2 can be provided in a user element to support the embodiments described above. In this regard, FIG. 6 is a schematic diagram of an exemplary user element 100, such as the wireless communication device 10 of FIG. 1, wherein the cross-segment power management system 12 of FIG. 2 can be provided.

Herein, the user element 100 can be any type of user elements, such as mobile terminals, smart watches, tablets, computers, navigation devices, access points, and like wireless communication devices that support wireless communications, such as cellular, wireless local area network (WLAN), Bluetooth, and near field communications. The user element 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

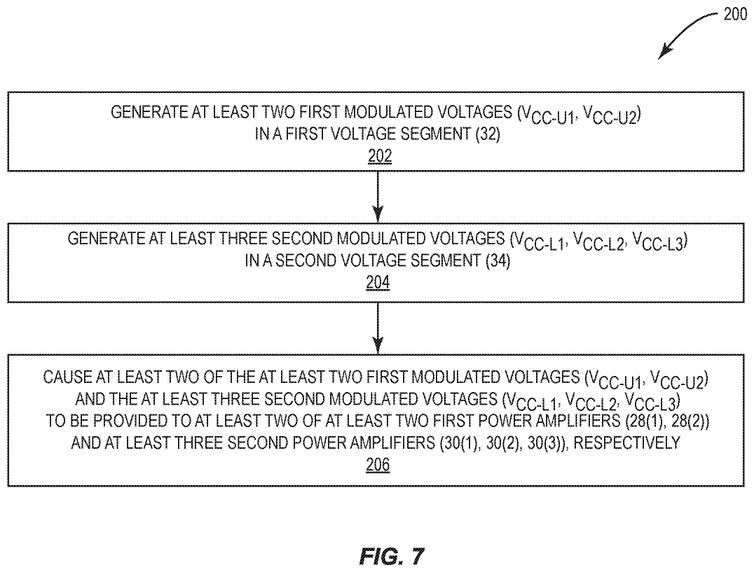

The wireless communication device 10 of FIG. 1 can be configured to support cross-segment power management in accordance with a process. In this regard, FIG. 7 is a flowchart of an exemplary process 200 whereby the wireless communication device 10 of FIG. 1 can be configured to support cross-segment power management according to embodiments of the present disclosure.

Herein the process 200 includes generating the at least two first modulated voltages V_{CC-U1}, V_{CC-U2} in the first voltage segment 32 (step 202). The process 200 also includes generating the at least three second modulated voltages V_{CC-L1}, V_{CC-L2}, V_{CC-L3} in the second voltage segment 34 (step 204). The process 200 also includes causing at least two of the at least two first modulated voltages V_{CC-U1}, V_{CC-U2} and the at least three second modulated voltages V_{CC-L1}, V_{CC-L2}, V_{CC-L3} to be provided to at least two of the at least two first power amplifiers 28(1), 28(2) and the at least three second power amplifiers 30(1), 30(2), 30(3), respectively (step 206).

Those skilled in the art will recognize improvements and modifications to the preferred embodiments of the present disclosure. All such improvements and modifications are considered within the scope of the concepts disclosed herein and the claims that follow.

1. A cross-segment power management system comprising:
a first amplifier segment comprising at least two first power amplifiers;
a second amplifier segment comprising at least three second power amplifiers;
a first voltage segment configured to generate at least two first modulated voltages;
a second voltage segment configured to generate at least three second modulated voltages; and
a control circuit configured to cause at least two of the at least two first modulated voltages and the at least three second modulated voltages to be provided to at least two of the at least two first power amplifiers and the at least three second power amplifiers, respectively.

2. The cross-segment power management system of claim 1, further comprises a cross-segment line coupled between the first voltage segment and the second voltage segment and configured to provide a low-frequency current from one of the first voltage segment and the second voltage segment to another one of the first voltage segment and the second voltage segment.

3. The cross-segment power management system of claim 2, wherein:
the first voltage segment comprises:
a first power management integrated circuit (PMIC) configured to generate one of the at least two first modulated voltages;
a first lightweight PMIC (PMCLite) configured to generate another one of the at least two first modulated voltages; and
a first switch circuit coupled to the first PMIC, the first PMICLite, and the cross-segment line; and
the second voltage segment comprises:
a pair of second PMICs configured to generate two of the at least three second modulated voltages, respectively; and
a second PMICLite configured to generate another one of the at least three second modulated voltages; and
a second switch circuit coupled to the pair of second PMICs, the second PMICLite, and the cross-segment line.

4. The cross-segment power management system of claim 3, wherein:
each of the first PMIC and the pair of second PMICs comprises a current modulation circuit configured to generate the low-frequency current and a voltage modulation circuit configured to generate a respective one of the at least two first modulated voltages and a respective two of the at least three second modulated voltages; and
each of the first PMICLite and the second PMICLite comprises only the voltage modulation circuit without the current modulation circuit and configured to generate a respective one of the at least two first modulated voltages and a respective one of the at least three second modulated voltages.

5. The cross-segment power management system of claim 4, wherein each of the first PMICLite and the second PMICLite has a smaller footprint than any of the first PMIC and the pair of second PMICs.

6. The cross-segment power management system of claim 3, wherein the control circuit is further configured to:
control the first switch circuit to couple the first PMIC to a selected one of the at least two first power amplifiers; and
control the second switch circuit to couple the pair of second PMICs to a selected two of the at least three second power amplifiers.

7. The cross-segment power management system of claim 3, wherein the control circuit is further configured to:
control the second switch circuit to couple each of the pair of second PMICs and the second PMICLite to a respective one of the at least three second power amplifiers; and
control the first switch circuit to couple the first PMIC to the cross-segment line to thereby provide the low-frequency current to the second PMICLite via the cross-segment line.

8. The cross-segment power management system of claim 3, wherein the control circuit is further configured to:
control the first switch circuit to couple the first PMIC and the first PMICLite to the at least two first power amplifiers;
control the second switch circuit to couple one of the pair of second PMICs to one of the at least three second power amplifiers; and
control the second switch circuit to couple another one of the pair of second PMICs to the cross-segment line to thereby provide the low-frequency current to the first PMICLite via the cross-segment line.

9. A wireless communication device comprising a cross-segment power management system comprising:
a first amplifier segment comprising at least two first power amplifiers;
a second amplifier segment comprising at least three second power amplifiers;
a first voltage segment configured to generate at least two first modulated voltages;
a second voltage segment configured to generate at least three second modulated voltages; and
a control circuit configured to cause at least two of the at least two first modulated voltages and the at least three second modulated voltages to be provided to at least two of the at least two first power amplifiers and the at least three second power amplifiers, respectively.

10. The wireless communication device of claim 9, further comprising:
at least two first antennas provided on a top edge of the wireless communication device and coupled to the first voltage segment; and
at least three second antennas provided on a bottom edge of the wireless communication device and coupled to the second voltage segment.

11. The wireless communication device of claim 10, wherein:
the first amplifier segment is provided closer to the at least two first antennas than to any of the at least three second antennas;
the second amplifier segment is provided closer to the at least three second antennas than to any of the at least two first antennas;
the first voltage segment is provided closer to the first amplifier segment than to the second amplifier segment; and
the second voltage segment is provided closer to the second amplifier segment than to the first amplifier segment.

12. The wireless communication device of claim 10, configured to support at least one of an uplink multiple-input multiple-output (UL-MIMO) transmission and an enhanced dual-connectivity (EN-DC) transmission using any two or more of the at least two first antennas and the at least three second antennas.

13. The wireless communication device of claim 9, wherein the cross-segment power management system further comprises a cross-segment line coupled between the first voltage segment and the second voltage segment and configured to provide a low-frequency current from one of the first voltage segment and the second voltage segment to another one of the first voltage segment and the second voltage segment.

14. The wireless communication device of claim 13, wherein:
the first voltage segment comprises:
a first power management integrated circuit (PMIC) configured to generate one of the at least two first modulated voltages;
a first lightweight PMIC (PMICLite) configured to generate another one of the at least two first modulated voltages; and
a first switch circuit coupled to the first PMIC, the first PMICLite, and the cross-segment line; and
the second voltage segment comprises:
a pair of second PMICs configured to generate two of the at least three second modulated voltages, respectively;
a second PMICLite configured to generate another one of the at least three second modulated voltages; and
a second switch circuit coupled to the pair of second PMICs, the second PMICLite, and the cross-segment line.

15. The wireless communication device of claim 14, wherein:
each of the first PMIC and the pair of second PMICs comprises a current modulation circuit configured to generate the low-frequency current and a voltage modulation circuit configured to generate a respective one of the at least two first modulated voltages and a respective two of the at least three second modulated voltages; and
each of the first PMICLite and the second PMICLite comprises only the voltage modulation circuit without the current modulation circuit and configured to generate a respective one of the at least two first modulated voltages and a respective one of the at least three second modulated voltages.

16. The wireless communication device of claim 15, wherein each of the first PMICLite and the second PMICLite has a smaller footprint than any of the first PMIC and the pair of second PMICs.

17. The wireless communication device of claim 14, wherein the control circuit is further configured to:
control the first switch circuit to couple the first PMIC to a selected one of the at least two first power amplifiers; and
control the second switch circuit to couple the pair of second PMICs to a selected two of the at least three second power amplifiers.

18. The wireless communication device of claim 14, wherein the control circuit is further configured to:
control the second switch circuit to couple each of the pair of second PMICs and the second PMICLite to a respective one of the at least three second power amplifiers; and
control the first switch circuit to couple the first PMIC to the cross-segment line to thereby provide the low-frequency current to the second PMICLite via the cross-segment line.

19. The wireless communication device of claim 14, wherein the control circuit is further configured to:
control the first switch circuit to couple the first PMIC and the first PMICLite to the at least two first power amplifiers;
control the second switch circuit to couple one of the pair of second PMICs to one of the at least three second power amplifiers; and
control the second switch circuit to couple another one of the pair of second PMICs to the cross-segment line to thereby provide the low-frequency current to the first PMICLite via the cross-segment line.

20. A method for providing cross-segment power management in a wireless communication device comprising:
generating at least two first modulated voltages in a first voltage segment;
generating at least three second modulated voltages in a second voltage segment; and
causing at least two of the at least two first modulated voltages and the at least three second modulated voltages to be provided to at least two of at least two first power amplifiers and at least three second power amplifiers, respectively.
